(19) United States
(12) Patent Application Publication
(10) Pub. No.: US 2013/0242310 A1
(43) Pub. Date: Sep. 19, 2013

(54) LIGHT SOURCE DEVICE INCLUDING SUPER LUMINESCENT DIODES, METHOD OF DRIVING THE SAME, AND OPTICAL TOMOGRAPHY IMAGING APPARATUS

(71) Applicant: CANON KABUSHIKI KAISHA, Tokyo (JP)

(72) Inventor: Toshimitsu Matsuu, Yokohama-shi (JP)

(73) Assignee: CANON KABUSHIKI KAISHA, Tokyo (JP)

(21) Appl. No.: 13/788,314

(22) Filed: Mar. 7, 2013

(30) Foreign Application Priority Data
Mar. 19, 2012 (JP) 2012-061491

(51) Int. Cl. H01L 33/00; G01B 9/02

(52) U.S. Cl. CPC H01L 33/0045; G01B 9/02091
USPC 356/479; 372/45.01; 372/38.02

(57) ABSTRACT

Provided is a light source device, including at least two super luminescent diodes being a first and second SLD, which are provided on a same substrate, the first and second SLD including: a same active layer having an emission spectrum having multiple peaks; a multiplexing portion for multiplexing beams of exit lights which respectively exit from the first and second SLD; and an optical output waveguide for outputting the multiplexed beams, the active layer, the multiplexing portion, and the optical output waveguide being formed on the substrate, in which the first SLD includes a first electrode portion for driving at a first current density, and is structured so that emission peaks on a long wavelength side are dominant, and the second SLD includes a second electrode portion for driving at a second current density, and is structured so that emission peaks on a short wavelength side are dominant.

### BACKGROUND OF THE INVENTION

1. Field of the Invention

The present invention relates to a light source device including super luminescent diodes, a method of driving the light source device, and an optical tomography imaging apparatus.

2. Description of the Related Art

Super luminescent diodes (hereinafter abbreviated as SLDs) are semiconductor light sources that have as broad a spectral distribution as those of light emitting diodes, and are yet capable of producing a relatively large optical output as semiconductor lasers are.

SLDs, with their characteristics, are attracting attention in the field of medicine and sensing technology where high resolution is demanded, and are used as, for example, the light source of an optical tomography imaging apparatus which utilizes an optical coherence tomography (OCT) system to obtain an optical tomography image of living tissue.

Broadening the spectrum is necessary in acquiring a high-resolution tomography image. A method of broadening the spectrum in SLDs is described in Quantum Electronics, Vol. 33, No. 6, pp. 471-473, 2003 (hereinafter referred to as Non Patent Literature 1), which uses an active layer having a single quantum well (hereinafter abbreviated as SQW) structure.

An SLD using SQW accomplishes a full width at half-maximum spectrum that is broad by utilizing the overlapping of emission spectra from two energy levels. In the SLD, attaining a large optical output and attaining a broad full width at half-maximum spectrum are in a trade-off relationship.

The SLD needs to be driven at a high injection current density in order to achieve a broad full width at half-maximum spectrum by emission spectra from two energy levels, in addition to achieving a large optical output.

However, when a broad full width at half-maximum spectrum is accomplished in the manner described in Non Patent Literature 1, there is a current density at which two emission peak intensities are equal to each other. Further current injection therefore increases optical output but raises the emission peak intensity of short-wavelength light as well, thereby reducing the full width at half-maximum spectrum.

In short, the conventional method has a problem in that the device cannot be driven at a certain level of current injection or higher despite the device's ability to produce a larger optical output due to the problem of spectrum characteristics.

### SUMMARY OF THE INVENTION

The present invention has been made in view of the problem described above, and therefore has an object to provide a light source device including super luminescent diodes that are capable of achieving a large optical output as well as a broad spectrum, a method of driving the light source device, and an optical tomography imaging apparatus.

According to an exemplary embodiment of the present invention, there is provided a light source device, including at least two super luminescent diodes being a first SLD and a second SLD, which are provided on a same substrate,
the first SLD and the second SLD including:

a same active layer having an emission spectrum having multiple peaks;

a multiplexing portion for multiplexing beams of exit lights which respectively exit from the first SLD and the second SLD; and

an optical output waveguide for outputting the multiplexed beams,

the active layer being formed on the same substrate,
in which the first SLD includes a first electrode portion for driving the first SLD at a first current density, and is structured so that emission peaks on a long wavelength side are dominant, and
the second SLD includes a second electrode portion for driving the second SLD at a second current density, and is structured so that emission peaks on a short wavelength side are dominant.

Further, according to an exemplary embodiment of the present invention, there is provided a method of driving a light source device,
the light source device including at least two super luminescent diodes being a first SLD and a second SLD, which are provided on a same substrate, the first SLD and the second SLD including:

a same active layer having an emission spectrum having multiple emission peaks;

a multiplexing portion for multiplexing beams of exit lights which respectively exit from the first SLD and the second SLD; and

an optical output waveguide for outputting the multiplexed beams,

the active layer being formed on the same substrate,
the light source device being configured to output the beams multiplexed in the multiplexing portion from the optical output waveguide,
the method including:
driving the first SLD at a first current density at which emission peaks on a long wavelength side of the emission spectrum are dominant; and
driving the second SLD at a second current density at which emission peaks on a short wavelength side of the emission spectrum are dominant.

According to the present invention, it is possible to provide a light source device including super luminescent diodes that are capable of achieving a large optical output as well as a broad spectrum, a method of driving the light source device, and an optical tomography imaging apparatus.

Further features of the present invention will become apparent from the following description of exemplary embodiments with reference to the attached drawings.

### BRIEF DESCRIPTION OF THE DRAWINGS

FIG. 1 is an overhead view illustrating a structural example of a light source device including SLDs according to a first embodiment of the present invention.

FIG. 2A is a spectrum graph showing the spectra of respective SLDs according to the first embodiment of the present invention.

FIG. 2B is a spectrum graph in which the spectra of the respective SLDs are combined according to the first embodiment of the present invention.

FIG. 3 is a perspective view illustrating the structural example of the light source device including SLDs according to the first embodiment of the present invention.

FIG. 4 is a sectional view taken along the line 4-4 of FIG. 1 to illustrate the layer structure of the light source device including SLDs according to the first embodiment of the present invention.

FIG. 5 is a sectional view taken along the line 5-5 of FIG. 1 to illustrate the layer structure of the light source device including SLDs according to the first embodiment of the present invention.

FIG. 6 is a diagram illustrating a structural example of an optical coherence tomography imaging apparatus according to a fourth embodiment which uses a light source device of the present invention.

FIG. 7 is a spectrum graph of an SLD according to the first embodiment of the present invention.

FIG. 8 is a spectrum graph of another SLD according to the first embodiment of the present invention.

FIG. 9 shows current-optical output characteristics of the respective SLDs according to the first embodiment of the present invention.

FIG. 10 is a spectrum graph showing the spectra of the respective SLDs according to the first embodiment of the present invention, and a spectrum that is obtained by combining the spectra of the SLDs.

FIG. 11 is a spectrum graph of a spectrum that is observed when an asymmetric quantum well is used in an active layer.

FIG. 12 is an overhead view illustrating a structural example of a light source device including SLDs according to a second embodiment of the present invention.

FIG. 13 is a perspective view illustrating the structural example of the light source device including SLDs according to the second embodiment of the present invention.

FIG. 14 is a perspective view illustrating a structural example of a light source device including SLDs according to a third embodiment of the present invention.

### DESCRIPTION OF THE EMBODIMENTS

The present invention enables a light source device including at least two super luminescent diodes (SLDs) to achieve a large optical output as well as a broad spectrum by setting one of the SLDs so that the emission peaks on the short wavelength side are dominant. A structural example of a light source device including SLDs according to an embodiment of the present invention is described below.

The light source device including SLDs according to the embodiment of the present invention includes at least two SLDs which are formed on the same substrate and have the same active layer, a multiplexing portion which multiplexes beams of exit lights of the at least two SLDs, and an optical output waveguide for outputting the multiplexed beams.

In each of the at least two SLDs, the emission spectrum of the active layer has multiple peaks.

The at least two SLDs include a first SLD which has a first electrode portion for driving the first SLD at a first current density and in which emission peaks on the long wavelength side are dominant, and a second SLD which has a second electrode portion for driving the second SLD at a second current density and in which emission peaks on the short wavelength side are dominant.

The multiple emission spectrum peaks of the active layer refer to peaks caused by having different energy levels, for example, emission peaks due to the ground level and a high order level, and emission peaks due to different energy levels in a multi-quantum well structure in which the composition or the well width is varied.

In this type of active layer, what emission peaks are caused varies depending on the SLD structure, the drive current density, and the like.

Emission peaks on the long wavelength side and emission peaks on the short wavelength side among the multiple peaks as used herein mean emission peaks at long wavelengths where energy is small and emission peaks at short wavelengths where energy is large in each of the SLDs including the first SLD and the second SLD, and do not mean that the wavelengths of the first SLD and the second SLD are long or short relative to each other.

Although heat may cause each emission peak to deviate by a few nm depending on the current density, emission peaks resulting from the same energy level are treated as the same peak.

In the second SLD, at least two emission peaks are caused by a second current and, of emission peaks at long wavelengths and emission peaks at short wavelengths, emission peaks at short wavelengths are dominant.

The second SLD is driven at a high current density so that emission peaks at short wavelengths are dominant. The optical output of the second SLD is therefore larger than that of an SLD driven at an intensity that causes emission peaks at long wavelengths and emission peaks at short wavelengths to be equal to each other. At the same time, the spectrum pattern of the second SLD does not follow the Gaussian curve and the full width at half-maximum spectrum is narrow.

In the first SLD, on the other hand, a first current is used and emission peaks at long wavelengths are dominant. The first SLD therefore cannot achieve a broad full width at half-maximum spectrum on its own.

When combined, however, these two SLDs achieve a broad full width at half-maximum spectrum by compensating each other's spectrum patterns which do not follow the Gaussian curve. In addition, with the second SLD where emission peaks at short wavelengths are dominant as an SLD that is larger in optical output than normal, a large optical output is attained as well as a broad spectrum.

The effect of the present invention is enhanced when a structure is employed that allows fewer emission peaks at short wavelengths in the first SLD than in the second SLD.

This is because, with the structure suppressing emission peaks at short wavelengths, the current density at which a current is injected can be set high in the compensation of portions of the spectrum of the first SLD where the emission peaks at long wavelengths, and a larger optical output is obtained.

This structure is realized by, for example, creating a difference between the first SLD and the second SLD with respect to the SLDs' emission regions, or in terms of element length in the optical waveguide direction or optical waveguide width.

Specifically, setting the element length in the optical waveguide direction larger in the first SLD than in the second SLD suppresses emission peaks at short wavelengths at an even higher current density.

The reason is that, when the element length is larger, stimulated amplification is more active in an SLD, which increases the rate of carrier consumption and reduces the chance of carrier supply reaching a level that contributes to emission at a short wavelength. Increasing the element length further enables an SLD to produce a larger optical output, and employing an SLD that is larger in element length than the second SLD as the first SLD therefore results in a larger optical output. Embodiments

Embodiments of the present invention are described below.

### First Embodiment

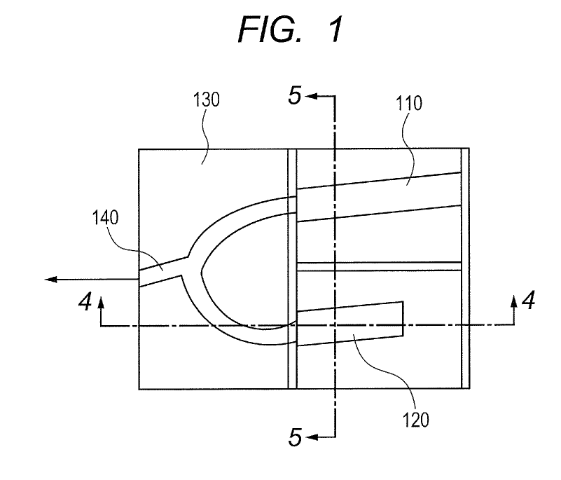

A structural example of a light source device including SLDs to which the present invention is applied is described as a first embodiment of the present invention with reference to FIGS. 1 and 3.

The light source device including SLDs of this embodiment includes two SLDs formed on the same substrate, an SLD 110 and an SLD 120, a multiplexing portion 130 for multiplexing beams of light that respectively exit from the SLD 110 and the SLD 120, and an optical output waveguide 140 for outputting the multiplexed light.

The SLD 110 and the SLD 120 have the same active layer which uses a single quantum well. A barrier layer in this case has a layer structure that enables the single quantum well to emit light on at least the first-order level as well.

The SLD 110 and the SLD 120 differ from each other in element length in the optical waveguide direction, and the element length of the SLD 110 is larger than that of the SLD 120.

The SLD 110, the SLD 120, the multiplexing portion 130, and the optical output waveguide 140 use an integrated twin guide structure and a Y-branched waveguide structure 230 to multiplex beams of exit light of the SLD 110 and the SLD 120 and output the light from one output portion.

The SLD 110 and the SLD 120 employ a ridge waveguide structure.

The layer structure in the light source device including SLDs of this embodiment is described next.

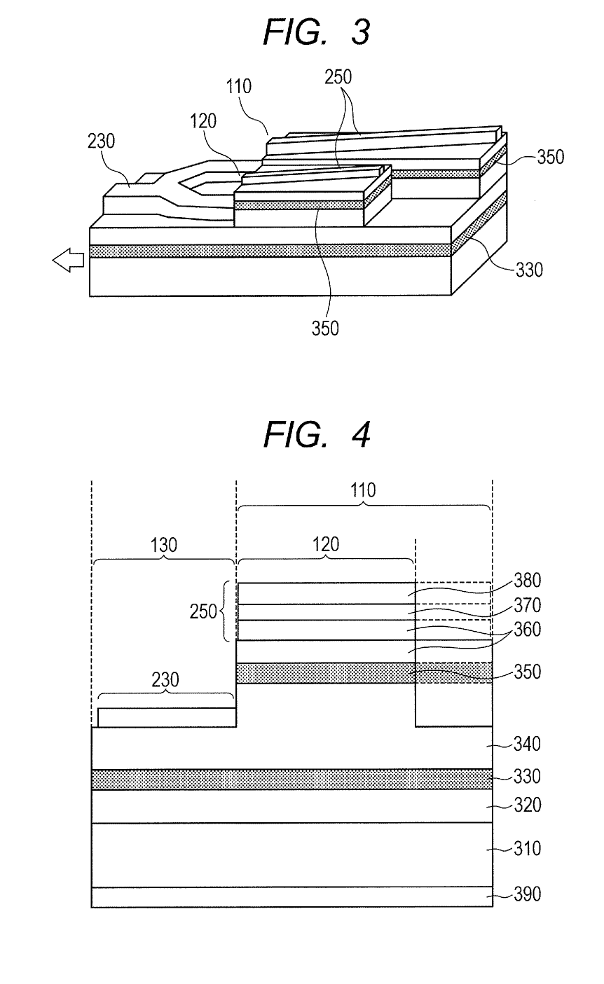

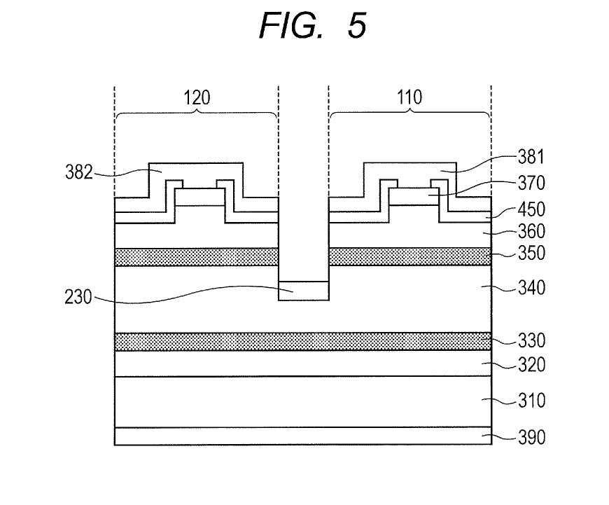

FIG. 4 is a sectional view taken along the line 4-4 of FIG. 1 and FIG. 5 is a sectional view taken along the line 5-5 of FIG. 1.

Some components such as an insulating film are omitted from FIGS. 4 and 5.

In the layer structure of this embodiment, the following layers are stacked on a substrate.

That is, stacked on an n-type GaAs substrate 310 are a layer of n-Al_{0.5}GaAs which serves as an n-type cladding layer 320, a layer of Al_{0.2}GaAs which serves as a waveguide layer 330, a layer of n-Al_{0.5}GaAs which serves as an n-type cladding layer 340, a single quantum well of InGaAs which serves as an active layer 350, a layer of p-Al_{0.5}GaAs which serves as a p-type cladding layer 360, and a heavily doped layer of p-GaAs which serves as a contact layer 370.

After ridge portions 250, the SLDs 110 and 120, and the multiplexing portion 130 are formed, an insulating film 450 and an upper electrode 380 are provided, and a lower electrode 390 is provided under the substrate.

The upper electrode 380 includes an upper electrode 381 and an upper electrode 382, which respectively drive the SLD 110 and the SLD 120 independently of each other. SiO₂ is used for the insulating film 450, Ti/Au is used for the upper electrode 380, and AuGe/Ni/Au is used for the lower electrode 390. The ridge portions of the SLD 110 and the SLD 120 are partially removed halfway down the p-type cladding layer 360 and the contact layer 370.

The SLD 110 and the SLD 120 are isolated from each other by etching halfway down the n-type cladding layer 340 which is below the active layer 350.

The SLD 110 and the SLD 120 which have different element lengths and the Y-branched waveguide 230 are formed by further partial etching that reaches halfway down the n-type cladding layer 340 and leaving the SLD 110, the SLD 120, and the Y-branched waveguide portion.

The SLD 110 and the SLD 120 have an element length of 1.0 mm and an element length of 0.7 mm, respectively, and both have a ridge width of 4 μm.

The ridge portions 250 are inclined by 7 degrees with respect to the vertical line of ridge end surfaces and the longitudinal direction of the ridges in order to prevent the reflection at the ridge end surfaces.

The angle of the Y-branched waveguide 230 in portions that are joined to the SLD 110 and the SLD 120 is inclined at an angle similar to the inclination angle of the SLD 110 and the SLD 120, here, 7 degrees. An output portion of the Y-branched waveguide 230 is also inclined by 7 degrees.

A multi-layer dielectric film may be added to the output portion of the Y-branched waveguide 230 and end surfaces of the SLD 110 and the SLD 120 in order to control the reflectance.

A procedure used in this embodiment to create the layers described above is described next.

First, the layers are formed on the GaAs substrate 310 by growing semiconductor layers sequentially with the use of, for example, metal organic chemical vapor deposition (MOCVD) process in the following manner.

That is, sequentially grown on the GaAs substrate 310 are the n-type cladding layer 320, the waveguide layer 330, the n-type cladding layer 340, the active layer 350, the p-type cladding layer 360, and the contact layer 370.

On the wafer where the layers are stacked, the ridge portions 250 are formed by semiconductor lithography process and semiconductor etching process that are common.

For instance, a dielectric film is formed by sputtering process from, e.g., SiO₂, and then semiconductor lithography process is used to form a stripe forming mask for forming ridges with a photo resist.

Then dry etching process is used to selectively remove other portions of the semiconductors than the stripe forming mask.

The removed portions reach halfway down the p-type cladding layer 360 to form the ridged shape that has, for example, a depth of 0.8 μm.

Next, photolithography process and dry etching process are used to remove the semiconductor layers except the tops of the SLD 110 and the SLD 120.

The semiconductor layers are etched here halfway down the n-type cladding layer 340, which is between the active layer 350 and the waveguide layer 330, to isolate the SLD 110 and the SLD 120 from each other.

Photolithography process and dry etching process are used to further remove the semiconductor layers except the SLD 110, the SLD 120, and the Y-branched waveguide 230, and the semiconductor layers are etched halfway down the n-type cladding layer 340 which is between the active layer 350 and the waveguide layer 330.

The integrated twin guide and the Y-branched waveguide 230 are formed in this manner, and enable the light source device to guide light generated in the SLD 110 and the SLD 120 to an output portion of the optical output waveguide 140.

Thereafter, the dielectric film 450 is formed on the semiconductor surface from, e.g., SiO₂, and portions of the SiO₂ above the ridge portions 250 are partially removed by photolithography process.

Next, vacuum evaporation process and lithography process are used to form the upper electrode 380 above each of the SLD 110 and the SLD 120. The upper electrode 380 is, for example, Ti/Au.

The lower electrode 390 is then formed from, for example, AuGe/Ni/Au. The electrodes and the semiconductors are made into an alloy in a high temperature nitrogen atmosphere in order to obtain the favorable electric characteristics.

Lastly, crystal surfaces are exposed on the end surfaces by cleaving, and both end surfaces are coated with a dielectric film for adjusting reflectance. The procedure is thus finished.

A method of driving the light source device including SLDs according to this embodiment is described next.

The drive currents of the SLD 110 and the SLD 120 are controlled respectively by the upper electrode 381 and the upper electrode 382 independently of each other.

In the SLD 110 and the SLD 120 where an InGaAs single quantum well is used for the active layer 350, emission peaks at long wavelengths due to the ground level are dominant when the SLDs are driven with the current density set low, and emission peaks at short wavelengths due to the first-order level are dominant when the SLDs are driven with the current density set high.

Here, in the case where only one emission peak at a long wavelength is recognizable because the intensity of emission peaks at short wavelengths is weak, the one emission peak is called an emission peak at a long wavelength.

Described first as the characteristics of SLDs that have different element lengths are spectrum characteristics and current-optical output characteristics that are observed when the drive current is varied between the SLD 110 and the SLD 120 (SLD 110: 1.0 mm, SLD 120: 0.7 mm).

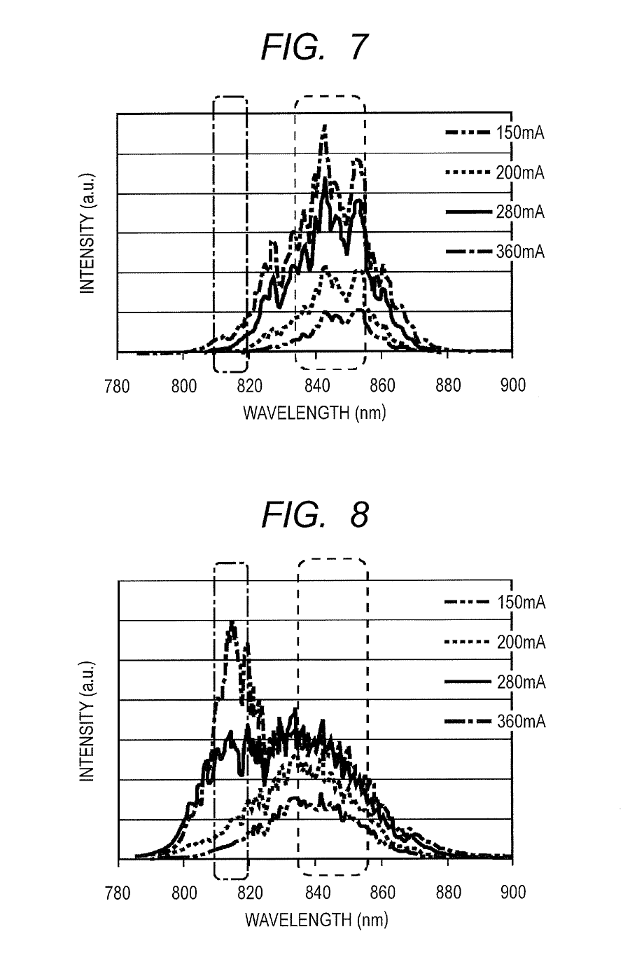

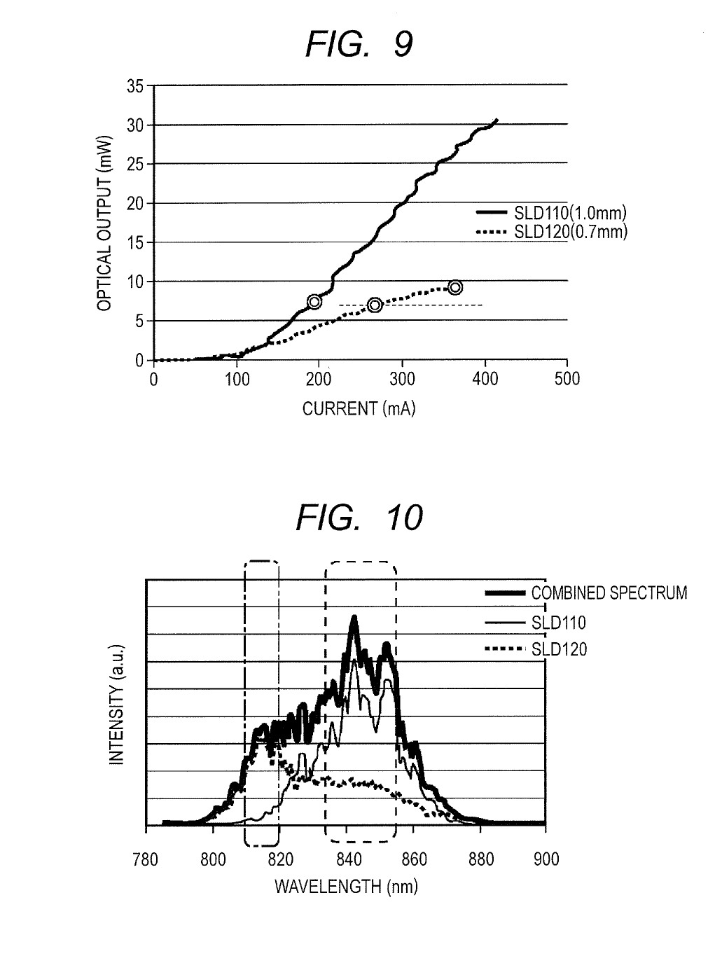

FIG. 7, FIG. 8, and FIG. 9 show the spectrum characteristics of the SLD 110, the spectrum characteristics of the SLD 120, and the current-optical output characteristics, respectively.

In this case, the emission peak at a long wavelength refers to a peak around 840 nm, and the emission peak at a short wavelength refers to a peak around 810 nm.

In the SLD 110 which is larger in element length than the SLD 120, emission peaks at long wavelengths are dominant and emission peaks at short wavelengths are suppressed despite a higher current density.

In the SLD 120, on the other hand, emission peaks at short wavelengths are caused even at a relatively low current density, and emission peaks at long wavelengths and emission peaks at short wavelengths are equal to each other in intensity at a current value of 280 mA, thus forming a Gaussian-like pattern.

The graph shows that, when the current is increased further, emission peaks at the short wavelengths become dominant at a current value of 360 mA, thereby causing the spectrum pattern to stop following the Gaussian pattern.

When two SLDs are used in an attempt to broaden the spectrum, the two SLDs are usually given different central wavelengths to compensate each other's wavelength bands and broaden the spectrum.

In the case of using the same active layer as in this embodiment, optical output is compensated by driving two SLDs 120, which have a broad spectrum, at 280 mA where emission peaks at long wavelengths and emission peaks at short wavelengths are equal to each other in intensity.

The relationship between optical output and full width at half-maximum spectrum of an SLD is determined by the element length of the SLD and, as the element length becomes larger, the optical output becomes larger but the full width at half-maximum spectrum becomes narrower.

Consequently, when all the SLDs used are the SLDs 120 which have a short element length, optical output is reduced as much as the full width at half-maximum spectrum is broadened.

In the case where the only SLDs used are the SLDs 110 which have a large element length and are large in optical output, on the other hand, the full width at half-maximum spectrum is narrower as shown in FIGS. 7 and 9.

This embodiment is structured so as to remedy these drawbacks, and sets a higher current density for the SLD 120 which has a small optical output and thus increases the optical output by driving the SLD 120 in a manner that causes emission peaks at short wavelengths to be dominant.

The SLD 120 is driven in combination with the SLD 110 which is large in optical output and in element length, to thereby balance spectrum broadening and optical output increase.

Specifically, the SLD 110 is driven at 200 mA and the SLD 120 is driven at 360 mA in this embodiment.

In other words, the SLDs 110 and 120 are driven so that emission peaks at long wavelengths are dominant in the SLD 110 whereas emission peaks at short wavelengths are dominant in the SLD 120.

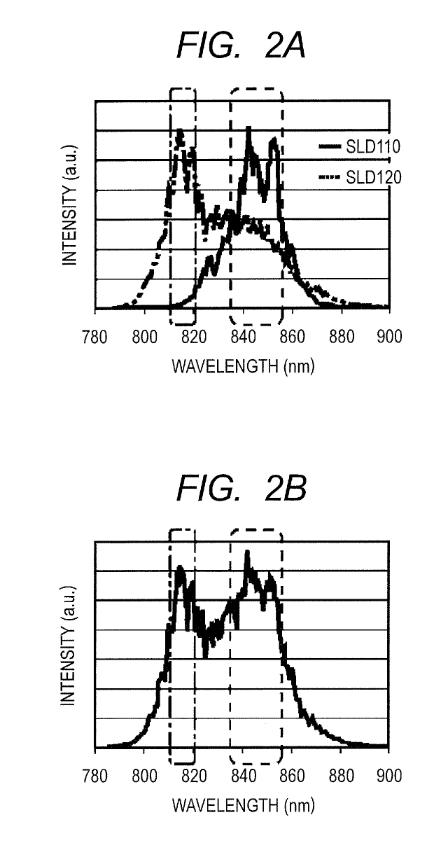

The spectra of the SLD 110 and the SLD 120 driven in this manner are shown in FIG. 2A, and a combined spectrum of the SLD 110 and the SLD 120 is shown in FIG. 2B.

The graphs confirm that combining the spectra of the SLD 110 and the SLD 120 yields a broad spectrum pattern in which emission peaks at short wavelengths and emission peaks at long wavelengths are substantially equal to each other in intensity.

As shown in FIG. 9, the optical output of the SLD 120 driven at 360 mA increases to 9.0 mW from 7.5 mW, which is the optical output of the SLD 120 driven at a current of 280 mA, which is usually used in spectrum broadening and at which emission peaks at long wavelengths and emission peaks at short wavelengths are equal to each other in intensity.

An additional optical output of 8 mW is obtained by driving the SLD 110, which is larger in optical output and has fewer emission peaks at short wavelengths than the SLD 120, at 200 mA, which brings the total optical output to 17 mW.

Compared to the case where two SLDs 120 driven at a current of 280 mA are placed side by side, a larger optical output is thus attained while accomplishing an equally broad spectrum.

To increase the optical output even more, the SLD 110 and the SLD 120 can be driven at, for example, 280 mA and 360 mA, respectively. The total optical output obtained in this case is 25 mW. The intensity of emission peaks at long wavelengths in this example is higher than that of emission peaks at short wavelengths as shown in FIG. 10, but a larger optical output than under the condition described above can be obtained.

A spectrum pattern and an optical output that are suitable for a specific use can be obtained by varying the drive condition in this manner.

To vary the drive condition while avoiding changing the full width at half-maximum spectrum too much, it is required that the difference between the sum of the emission peak intensities of the two SLDs at short wavelengths and the sum of the emission peak intensities of the two SLDs at long wavelengths not be twice or more.

In other words, the relationship “½A<B<2A” needs to be satisfied, where “A” represents the sum of intensities of the emission peaks of the first SLD and the second SLD on the short wavelength side, and “B” represents the sum of intensities of the emission peaks of the first SLD and the second SLD on the long wavelength side.

In addition to the drive condition, the element lengths of the SLDs may be changed to suit individual cases, and these may be combined under an appropriate condition to obtain an arbitrary spectrum pattern and optical output.

The present invention is not limited to the forming method, the semiconductor materials, the electrode materials, the dielectric materials, and the like that are disclosed in the embodiment of the present invention, and other methods and materials can be used as long as the choice does not depart from the spirit of the present invention.

For instance, the substrate used may be a p-type GaAs substrate and, in this case, the conductivity types of the semiconductor layers are changed accordingly.

The active layer which uses a single quantum well here may instead use, for example, a multi-quantum well or an asymmetric multi-quantum well in which the well width and the composition ratio are varied.

In that case, an emission peak at a short wavelength may be of light emission due to the first-order level whereas an emission peak at a long wavelength is of light emission due to the ground level as in the case where a single quantum well is used.

Alternatively, because each quantum well structure is different, emission peaks due to different energy levels that correspond to the different quantum well structures may be treated as an emission peak at a short wavelength and an emission peak at a long wavelength.

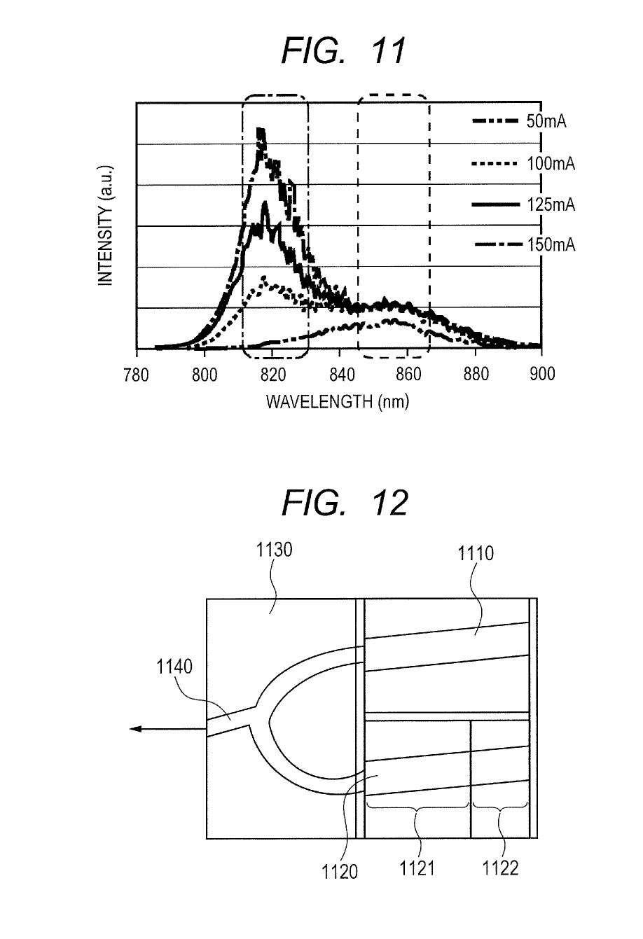

For instance, when the active layer uses an asymmetric multi-quantum well formed from different well layer materials, specifically, InGaAs, GaAs, and AlGaAs, spectrum characteristics of FIG. 11 are observed.

Emission peaks at long wavelengths which are dominant when the drive current density is low are peaks around 860 nm, and emission peaks at short wavelengths which are dominant when the drive current density is high are peaks around 820 nm. Raising the current density increases the intensity of emission peaks at short wavelengths twice or more the intensity of emission peaks at long wavelengths. In the case of an active layer having such a spectrum, there is a large difference from an optical output produced when the active layer is driven with a drive current at which emission peaks at long wavelengths and emission peaks at short wavelengths are equal to each other in intensity, and the effect of applying the present invention is enhanced.

The materials are also not limited to those given above, and light emitting materials such as GaAs, GaInP, AlGaInN, AlGaInAsP, and AlGaAsSb may be used.

The ridge width is not limited to 4 μm and may be changed to suit individual cases.

This embodiment employs an SLD structure in which a ridge portion is used for each SLD and the ridges are inclined. However, any structure that operates as an SLD can be employed, for example, a structure that prevents reflection with a window structure instead of an inclined ridge.

The multiplexing portion is not limited to the Y-branched multiplexer employed here, and other multiplexers that have a multiplexing function such as a multi-mode interference (MMI) multiplexer may be used.

The SLD 110, the SLD 120, and the multiplexing portion 130 here are built monolithically. The structure of this embodiment may instead be accomplished by building only the SLD 110 and the SLD 120 monolithically and multiplexing beams of light from the SLDs 110 and 120 with a fiber coupler or the like in the multiplexing portion 130.

This embodiment, which uses two SLDs, may also be structured so that beams of light from three or more SLDs are multiplexed.

In this case, every SLD may have a different element length, or, to compensate the emission peaks at short wavelengths more, the element length may be determined so that, for example, two SLDs are given two different short element lengths while one SLD is given a large element length.

### Second Embodiment

A structural example in which two SLDs, an SLD 1110 and an SLD 1120, have the same element length is described as a second embodiment of the present invention.

The SLD 1120 has an upper electrode that is divided into two in the optical waveguide direction.

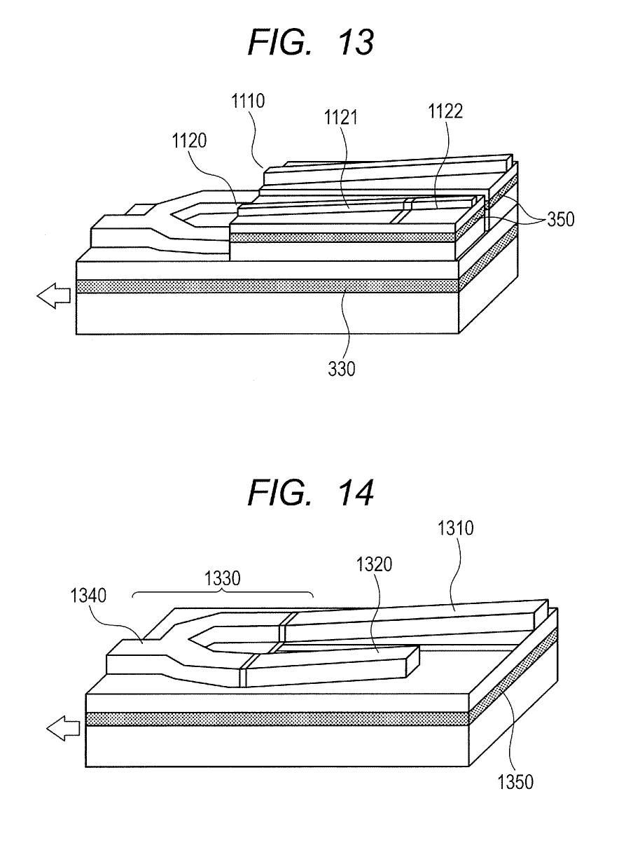

The structure of this embodiment is described with reference to an overhead view of FIG. 12 and a perspective view of FIG. 13. A light source device of this embodiment includes a multiplexing portion and an optical output waveguide for outputting the multiplexed light.

Specifically, as in the first embodiment, the light source device includes two SLDs formed on the same substrate, the SLD 1110 and the SLD 1120, a multiplexing portion 1130 for multiplexing beams of light that respectively exit from the SLD 1110 and the SLD 1120, and an optical output waveguide 1140 for outputting the multiplexed light. The SLD 1110 and the SLD 1120 have the same active layer 350.

The two divided pieces of electrode create different current injection regions, a region 1121 and a region 1122, in the SLD 1120.

Ti/Au of the upper electrode and a GaAs contact layer are removed by, for example, photolithography process and wet etching process from a region between the region 1121 and the region 1122, thereby forming the region 1121 and the region 1122 into separate current injection regions.

Here, the element length of the SLD 1110 and the SLD 1120 is 1.0 mm, and the lengths of the regions 1121 and 1122 of the SLD 1120 are 0.7 mm and 0.3 mm, respectively, in the optical waveguide direction. The distance between the region 1121 and the region 1122 is a few μm.

How the SLD 1110 and the SLD 1120 are driven in this embodiment is described next.

In the SLD 1120, a current is injected to the region 1121 in a normal manner and no current a weak current is injected to the region 1121.

Then, the region 1122 of the SLD 1120 works as an absorption region despite the fact that the SLD 1110 and the SLD 1120 have the same element length. The substantial emission region of the SLD 1120 is therefore the region 1121, and the effect of varying the element length in the manner of the first embodiment is obtained.

In other words, the SLD 1110 can be considered as an SLD that has a larger element length than the SLD 1120. Driving the SLD 1110 and the region 1121 of the SLD 1120 in the manner of the first embodiment therefore yields a broad spectrum and a large optical output.

Employing this structure allows the use of a cleaved surface in both the SLD 1110 and the SLD 1120, which leads to the stabilizing of characteristics.

The SLD 1120 alone is divided into two different current injection regions here. Alternatively, the SLD 1120 may be divided into three or more regions, or the SLD 1110 may be divided into multiple regions as well.

In this case, the spectrum pattern can be controlled more arbitrarily by varying the amount of current injection from one region to another. Dividing each SLD into multiple current injection regions in this manner may be applied to the first embodiment.

The ridge width may be varied between the SLD 1110 and the SLD 1120 which have the same element length to control the current density and drive the SLDs 1110 and 1120 in a manner that causes emission peaks at long wavelengths to be dominant in the SLD 1110 and emission peaks at short wavelengths to be dominant in the SLD 1120.

The ridge width may be varied by, for example, in addition to simply varying the widths of the SLD 1110 and the SLD 1120, employing a tapered structure in which the ridge in each SLD becomes narrower toward the multiplexing portion along the optical waveguide direction.

### Third Embodiment

The following structural example is described as a third embodiment of the present invention with reference to FIG. 14.

That is, this embodiment employs a structure in which two SLDs, an SLD 1310 and an SLD 1320, a multiplexing portion 1330 for multiplexing beams of light that respectively exit from the SLD 1310 and the SLD 1320, and an optical output waveguide 1340 for outputting the multiplexed light are all formed on the same substrate and have the same active layer 1350.

As illustrated in FIG. 14, this embodiment is structured so that an n-type cladding layer, an active layer, a p-type cladding layer, and a contact layer are stacked on an n-type substrate.

Ridge portions of the SLD 1310 and the SLD 1320, the multiplexing portion 1330, and the optical output waveguide 1340 are formed by semiconductor lithography process and semiconductor etching process that are common. An upper electrode is formed on each of the SLD 1310, the SLD 1320, and the multiplexing portion 1330 so that the three can be driven with a current independently of one another.

Ti/Au of the upper electrodes and a GaAs contact layer are removed by, for example, photolithography process and wet etching process from a region between the SLD 1310 and the multiplexing portion 1330 and from a region between the SLD 1320 and the multiplexing portion 1330, thereby electrically isolating one from the other.

In this embodiment in which an electrode is formed above the multiplexing portion 1330 in addition to electrodes above the SLD 1310 and the SLD 1320, a current can be injected to the multiplexing portion 1330 as well.

Injecting a current to the multiplexing portion 1330 and the optical output waveguide 1340 at some current density prevents the absorption of guided light in the multiplexing portion 1330 and the optical output waveguide 1340.

### Fourth Embodiment

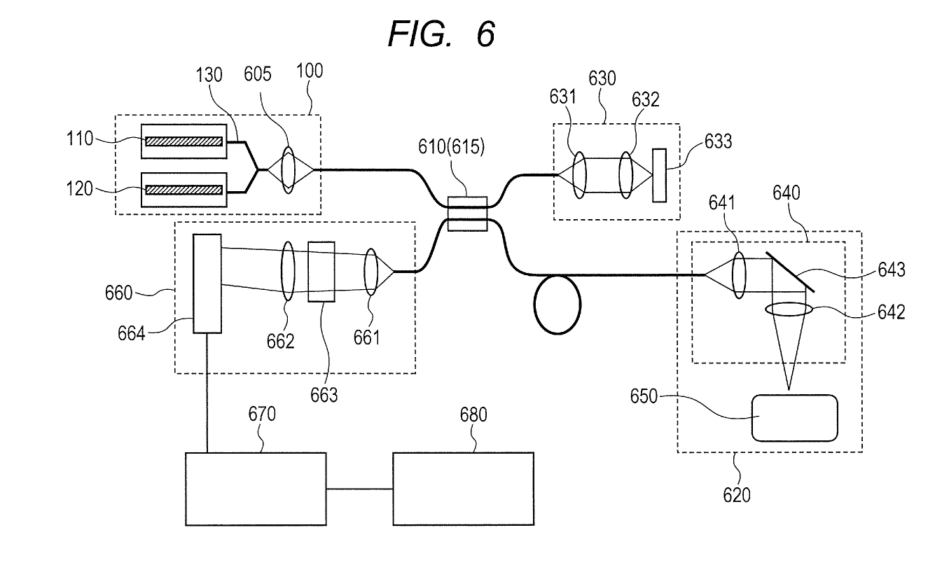

A structural example of an OCT apparatus (optical tomography imaging apparatus) including a light source device of the present invention is described as a fourth embodiment of the present invention with reference to FIG. 6.

As illustrated in FIG. 6, the OCT apparatus of this embodiment includes an optical output portion 100, a light splitting portion 610 for splitting the light that exits from the optical output portion 100 into reference light and measurement light, and a reference light reflecting portion 630.

The OCT apparatus also includes a measuring portion 620 which includes a measurement object 650 and an irradiation optical system 640 for irradiating the measurement object 650 with light to guide the reflected light thereof, and an interfering portion 615 for causing interference between the measurement light that has been reflected and the reference light that has been reflected by a reference mirror which constitutes a reference portion.

The OCT apparatus further includes a light detecting portion 660 which detects the interfering light provided by the interfering portion, an image processing portion 670 which executes the image processing (obtains a tomography image) based on the light detected by the light detecting portion 660, and an image output monitor portion 680.

A specific structure of the OCT apparatus is described below.

The optical output portion 100 includes the SLD 110 and the SLD 120, the multiplexing portion 130 which couples two beams of exit light, and a lens 605 which couples light to an optical fiber.

Light enters the light splitting portion 610 via an optical fiber to be demultiplexed into reference light and measurement light, and a part of the demultiplexed light enters the reference light reflecting portion 630.

Here, the same fiber coupler is used as the light splitting portion 610 and the interfering portion 615.

The reference light reflecting portion 630 includes collimator lenses 631 and 632 and a reflecting mirror 633. Light is reflected by the reflecting mirror 633 to enter the optical fiber again.

The measurement light which is the other beam of light created by the demultiplexing of light from the optical fiber in the light splitting portion 610 enters the measuring portion 620.

The irradiation optical system 640 of the measuring portion 620 includes collimator lenses 641 and 642 and a reflecting mirror 643 for bending a light path by 90°. The irradiation optical system 640 has a role of causing the incident light to irradiate the measurement object 650 and coupling the incident light that is reflected by the measurement object 650 to the optical fiber again.

The beams of light returning from the reference light reflecting portion 630 and the measuring portion 620 pass through the interfering portion 615 and enter the light detecting portion 660. The light detecting portion 660 includes collimator lenses 661 and 662, a spectroscope 663, and a line sensor 664 for obtaining the spectrum information of light that is dispersed by the spectroscope 663. The spectroscope 663 uses a grating.

The light detecting portion 660 is structured to obtain the spectrum information of light entering the light detecting portion 660. The information obtained by the light detecting portion 660 is converted into an image by the image processing portion 670 which executes conversion to a tomography image. Tomography image information which is the final output is thus obtained. The tomography image information is displayed as a tomography image on the image output monitor portion 680 which includes a display screen of a personal computer or the like.

The feature of this embodiment is the optical output portion 100 which is capable of producing a large optical output of a broad spectrum when a light source device including SLDs of the present invention is used. Tomography image information that is high in depth resolution can therefore be obtained.

This OCT apparatus is useful for tomography imaging in the practices of ophthalmology, dentistry, dermatology, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-061491, filed Mar. 19, 2012, which is hereby incorporated by reference herein in its entirety.

What is claimed is:

1. A light source device, comprising at least two super luminescent diodes being a first SLD and a second SLD, which are provided on a same substrate,
the first SLD and the second SLD comprising:
a same active layer having an emission spectrum having multiple peaks;
a multiplexing portion for multiplexing beams of exit lights which respectively exit from the first SLD and the second SLD; and
an optical output waveguide for outputting the multiplexed beams,
the active layer being formed on the same substrate,
wherein the first SLD comprises a first electrode portion for driving the first SLD at a first current density, and is structured so that emission peaks on a long wavelength side are dominant, and
the second SLD comprises a second electrode portion for driving the second SLD at a second current density, and is structured so that emission peaks on a short wavelength side are dominant.

2. The light source device according to claim 1, wherein the first SLD has a larger element length in an optical waveguide direction than an element length of the second SLD in the optical waveguide direction.

3. The light source device according to claim 1, wherein the first current density is lower than the second current density.

4. The light source device according to claim 1, wherein the active layer comprises a single quantum well.

5. The light source device according to claim 4,
wherein emission due to a ground level is dominant among the emission peaks on the long wavelength side, and
emission due to a first-order level is dominant among the emission peaks on the short wavelength side.

6. The light source device according to claim 1, wherein the first SLD and the second SLD have a same element length in an optical waveguide direction.

7. The light source device according to claim 1, wherein at least one of the first SLD and the second SLD comprises an electrode that is divided into at least two pieces in the optical waveguide direction.

8. The light source device according to claim 1, wherein, in the second SLD, the emission peaks on the short wavelength side at the second current density have a peak intensity twice or more higher than a peak intensity of the emission peaks on the long wavelength side.

9. The light source device according to claim 1, wherein the multiplexing portion and the optical output waveguide are formed monolithically with at least the two super luminescent diodes.

10. The light source device according to claim 9, wherein the multiplexing portion and the optical output waveguide have the same active layer as the active layer of the first SLD and the second SLD.

11. The light source device according to claim 1, wherein the multiplexing portion comprises an electrode.

12. A method of driving a light source device,
the light source device comprising at least two super luminescent diodes being a first SLD and a second SLD, which are provided on a same substrate, the first SLD and the second SLD comprising:
a same active layer having an emission spectrum having multiple emission peaks;
a multiplexing portion for multiplexing beams of exit lights which respectively exit from the first SLD and the second SLD; and
an optical output waveguide for outputting the multiplexed beams,
the active layer being formed on the same substrate,
the light source device being configured to output the beams multiplexed in the multiplexing portion from the optical output waveguide,
the method comprising:
driving the first SLD at a first current density at which emission peaks on a long wavelength side of the emission spectrum are dominant; and
driving the second SLD at a second current density at which emission peaks on a short wavelength side of the emission spectrum are dominant.

13. The method of driving a light source device according to claim 12,
wherein at least one of the first SLD and the second SLD comprises an electrode that is divided into at least two pieces in an optical waveguide direction, and
the first SLD and the second SLD are driven at current densities that are set independently of each other.

14. The method of driving a light source device according to claim 12, wherein, in an emission spectrum resulting from driving the first SLD at the first current density and an emission spectrum resulting from driving the second SLD at the second current density, the following relationship is satisfied: ½A<B<2A
where “A” represents a sum of intensities of the emission peaks of the first SLD and the second SLD on the short wavelength side, and “B” represents a sum of intensities of the emission peaks of the first SLD and the second SLD on the long wavelength side.

15. An optical tomography imaging apparatus, comprising:
the light source device according to claim 1;
a measuring portion which irradiates a measurement object with light from the light source device to guide the light reflected from the measurement object;
a reference portion which irradiates a reference mirror with light from the light source device to guide the light reflected from the reference mirror;
an interfering portion which causes interference between the light reflected from the measuring portion and the light reflected from the reference portion;
a light detecting portion which detects interfering light from the interfering portion; and
an image processing portion which obtains a tomography image of the measurement object based on the interfering light detected by the light detecting portion.
